(19) United States
(12) Patent Application Publication
(10) Pub. No.: US 2022/0020854 A1
(43) Pub. Date: Jan. 20, 2022

(54) SEMICONDUCTOR DEVICE AND METHOD FOR MANUFACTURING SAME

(71) Applicant: CHANGXIN MEMORY TECHNOLOGIES, INC., Hefei City (CN)

(72) Inventor: KeJun MU, Hefei City (CN)

(73) Assignee: CHANGXIN MEMORY TECHNOLOGIES, INC., Hefei City (CN)

(21) Appl. No.: 17/449,455

(22) Filed: Sep. 29, 2021

Related U.S. Application Data
(63) Continuation of application No. PCT/CN2021/076139, filed on Feb. 9, 2021.

(30) Foreign Application Priority Data
Feb. 25, 2020 (CN) 202010116555.8

(51) Int. Cl. H01L 29/40; H01L 29/417; H01L 29/45; H01L 21/285

(52) U.S. Cl. CPC H01L 29/401; H01L 29/41725; H01L 27/108; H01L 21/28518; H01L 29/45

(57) ABSTRACT

A semiconductor device includes: a doped region having a first conductive type in which a source region and/or a drain region having a second conductive type is formed; padding layers having the second conductive type formed on the source region and/or the drain region and in contact with the source region and/or the drain region; an interlayer dielectric layer formed on the doped region and the padding layers; electrodes penetrating through the dielectric layer and extending into the padding layers so as to be electrically connected with the padding layers.

### CROSS-REFERENCE TO RELATED APPLICATIONS

This is a continuation of International Application No. PCT/CN2021/076139 filed on Feb. 9, 2021, which claims priority to Chinese Patent Application No. 202010116555.8 filed on Feb. 25, 2020. The disclosures of these applications are hereby incorporated by reference in their entirety.

### BACKGROUND

When a semiconductor device is manufactured, a source region and a drain region having a second conductive type can be formed on a doped region having a first conductive type. When an inversion layer is formed on the doped region between the source region and the drain region, a current path can be formed. In a conventional process, electrodes penetrate through a dielectric layer and extend into the source region and the drain region so as to be in contact with the source region and the drain region.

### SUMMARY

The disclosure relates to a semiconductor device and a method for manufacturing the same.

According to some examples, one aspect of this disclosure provides a method for manufacturing a semiconductor device. The method includes the following operations.

A source region and/or a drain region is formed on a surface layer of a doped region, the doped region has a first conductive type, and the source region and/or the drain region has a second conductive type.

A first dielectric layer is formed on the doped region, and the first dielectric layer is arranged with windows exposing the source region and/or the drain region.

Padding layers in contact with the source region and/or the drain region are formed through the windows, and the padding layers have the second conductive type.

A second dielectric layer is formed on the first dielectric layer and the padding layers, and the second dielectric layer is provided with contact holes penetrating through the second dielectric layer and extending into the padding layers.

And, the contact holes are filled with an electrode material to form electrodes in contact with the padding layers.

According to some examples, one aspect of this disclosure provides a semiconductor device. The semiconductor device includes the followings: a doped region, a source region and/or a drain region being formed on a surface layer of the doped region, the doped region having a first conductive type, and the source region and/or the drain region having a second conductive type; padding layers formed on the source region and/or the drain region and in contact with the source region and/or the drain region, the padding layers having a second conductive type; a dielectric layer formed on the doped region and the padding layers; and electrodes penetrating through the dielectric layer and extending inside the padding layers so as to be electrically connected with the padding layers.

Details of one or more examples of this disclosure will be proposed in the following drawings and descriptions. Other features and advantages of this disclosure will become apparent from the specification, drawings and the claims.

### BRIEF DESCRIPTION OF THE DRAWINGS

In order to more clearly illustrate the examples of this disclosure or technical solutions in the traditional technology, accompanying drawings required in examples of the disclosure will be further described below briefly. It is apparent that the drawings illustrated in the following description only show some examples of the disclosure. Those skilled in the art can also obtain other drawings according to these drawings without any creative work.

FIG. 1 shows a partial cross-sectional view of a semiconductor device in the traditional technology.

FIG. 2 shows a flow chart of steps of a method for manufacturing a semiconductor device in this disclosure.

FIG. 3A is a first schematic diagram illustrating structures presented in related steps of a method for manufacturing a semiconductor device in an example.

FIG. 3B is a second schematic diagram illustrating structures presented in related steps of a method for manufacturing a semiconductor device in an example.

FIG. 3C is a third schematic diagram illustrating structures presented in related steps of a method for manufacturing a semiconductor device in an example.

FIG. 3D is a fourth schematic diagram illustrating structures presented in related steps of a method for manufacturing a semiconductor device in an example.

FIG. 3E is a fifth schematic diagram illustrating structures presented in related steps of a method for manufacturing a semiconductor device in an example.

FIG. 3F is a sixth schematic diagram illustrating structures presented in related steps of a method for manufacturing a semiconductor device in an example.

### LIST OF REFERENCE NUMERALS

100: semiconductor substrate, 110: doped region, 111: source region, 112: drain region, 130: isolation structure, 200: gate structure, 210: gate dielectric layer, 220: gate conductive layer, 300: interlayer dielectric layer, 310: first dielectric layer, 311: window, 320: second dielectric layer, 321: contact hole, 400: padding layer, 500: metal silicide, 600: electrode

### DETAILED DESCRIPTION

In electrical performance tests of the semiconductor device, the semiconductor device will have relatively obvious leakage phenomenon. Lager leakage will cause greater power consumption of the device, thereby affecting the stability and service life of the device.

Hereinafter, the disclosure will be described more fully with reference to the accompanying drawings in order to facilitate an understanding of the disclosure. Preferred examples of the disclosure are shown in the accompanying drawings. However, the disclosure may be implemented in many different forms and is not limited to the examples described herein. Rather, the purpose of providing these examples is to make the contents of the disclosure more thorough and comprehensive.

Unless otherwise defined, all technical and scientific terms used herein have the same meanings as commonly understood by those skilled in the art to which the disclosure belongs. The terms used in the specification of the disclosure herein are merely for the purpose of describing specific embodiments, and are not intended to limit the disclosure. As used herein, the term “and/or” includes any and all combinations of one or more of the relevant listed items.

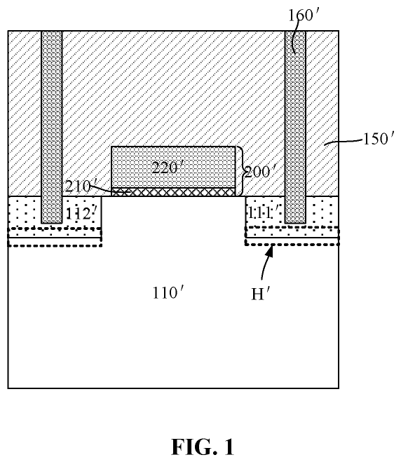

FIG. 1 shows a partial cross-sectional view of a semiconductor device in the traditional technology. In the traditional technology, a source region 111′ and/or a drain region 112′ is formed on an upper surface layer of a doped region 110′, and electrodes 160′ penetrate through a dielectric layer 150′ and extend into the source region 111′ and the drain region 112′ so as to be electrically connected with the source region 111′ and the drain region 112′ respectively. In a specific process, firstly, contact holes penetrating through the dielectric layer 150′ and extending into the source region 111′ and the drain region 112′ are first provided, and then, the contact holes are filled with the electrode material to form the electrodes 160′. After research, the applicant found that the source region 111′ (or the drain region 112′) and the doped region 110′ which are in contact with each other form a PN junction, and a depletion region is formed at a contact surface of the source region 111′ (or the drain region 112′) and the doped region 110′. If the etching process is not properly controlled when forming the contact holes, it is easy to cause the contact holes to extend too deeply in the source region 111′ (or the drain region 112′), which will make the distances between the electrodes 160′ and the depletion regions H′ too small or even the electrodes 160′ in contact with the depletion regions H′, thereby causing junction leakage.

To this end, this disclosure proposes a new method for manufacturing a semiconductor device, which can reduce the above-mentioned junction leakage.

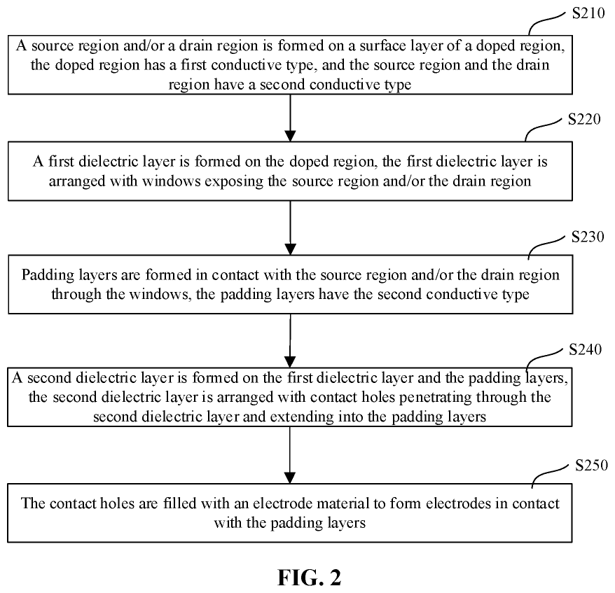

FIG. 2 shows a flow chart of steps of a method for manufacturing a semiconductor device. The method includes the following steps.

At step S210, a source region and/or a drain region is formed on a surface layer of a doped region. The doped region has a first conductive type, and the source region and/or the drain region has a second conductive type.

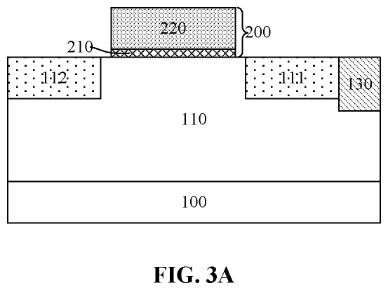

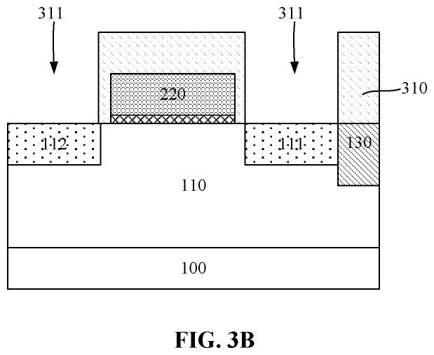

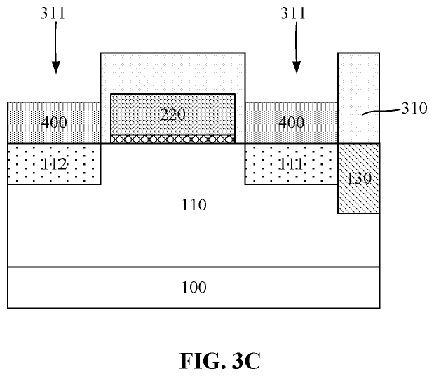

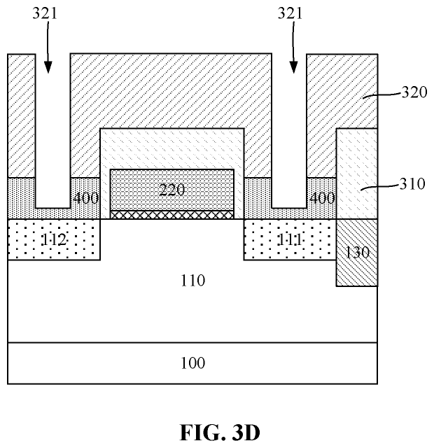

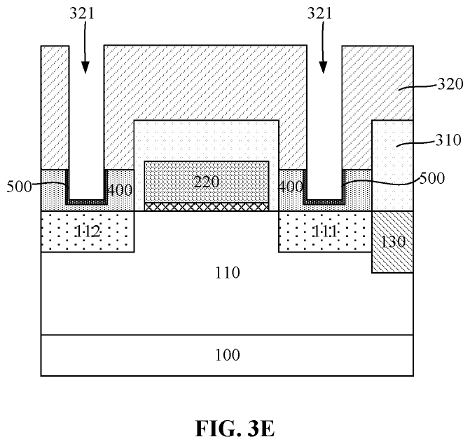

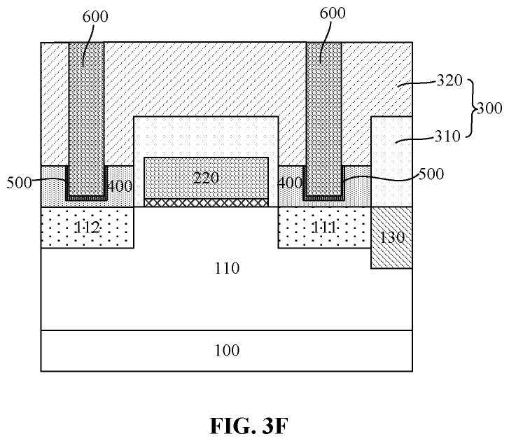

As shown in FIG. 3A, the surface layer of the doped region 110 having a first conductive type is selectively doped to form the source region 111 and/or the drain region 112. The doped region 110 has the first conductive type, and the source region 111 and the drain region 112 have the second conductive type. That is, the conductive type of the doped region 110 is opposite to the conductive type of the source region 111, and the conductive type of the doped region 110 is opposite to the conductive type of the drain region 112. The first conductive type is one of a P type and an N type, and the second conductive type is the other one of the P type and the N type. For example, when the first conductive type is the P type, the second conductive type is the N type; and when the first conductive type is the N type, the second conductive type is the P type. The conductive type of the doped region 110 is opposite to the conductive type of the source region 111 and the drain region 112. When an inversion layer is formed in the doped region 110 between the source region 111 and the drain region 112, the source region 111 and the drain region 112 can form a current path.

In an example, the doped region 110 may be a semiconductor substrate 100 having the first conductive type or an epitaxial layer having the first conductive type formed on the semiconductor substrate 100, or may be a well region having the first conductive type formed by doping the inside or epitaxial layer of the semiconductor substrate 100.

In an example, an isolation structure 130 is formed in the doped region 110, and adjacent source regions are isolated by the isolation structure 130.

At step S220, a first dielectric layer is formed on the doped region, and the first dielectric layer is arranged with windows exposing the source region and/or the drain region.

As shown in FIG. 3B, the first dielectric layer 310 is formed on the doped region 110, and the first dielectric layer 310 is arranged with windows 311 exposing the source region 111 and/or the drain region 112. Specifically, the first dielectric layer 310 may be silicon oxide.

In an example, the process of obtaining the above-mentioned first dielectric layer 310 may include the following operations.

The first dielectric layer 310 is deposited on the doped region 110, and the first dielectric layer 310 covers an entire upper surface of the doped region 110.

An upper surface of the first dielectric layer 310 is ground so that the first dielectric layer 310 has a flat upper surface.

A mask is formed on the first dielectric layer 310, arrangement positions of the windows 311 are defined through the mask, and the arrangement positions are directly opposite to the source region 111 and/or the drain region 112.

The first dielectric layer 310 is etched to form the windows 311 exposing the source region 111 and/or the drain region 112.

And, the mask is removed.

At step S230, padding layers in contact with the source region and/or the drain region are formed through the windows, and the padding layers have a second conductive type.

As shown in FIG. 3C, the padding layers 400 in contact with the source region 111 and/or the drain region 112 are formed in the windows 311, and the padding layers 400 also have a second conductive type. That is, the conductive type of the padding layers 400 is consistent with the conductive type of the source region 111 and the drain region 112. Further, the doping concentration of the padding layers 400 needs to be higher than the doping concentration of the source region 111 and/or the drain region 112, so as to form an ohmic contact between the padding layers 400 and the source region/the drain region. In an example, the thickness of the padding layers 400 does not exceed the depth of the windows 311. That is, the padding layers 400 are only formed in the windows 311 to define the shape of the padding layers 400. Specifically, the thickness of the first dielectric layer 310 can be designed according to the required thickness of the padding layers 400, so that the depth of the windows 311 is greater than or equal to the thickness of the padding layers 400.

In an example, the material of the padding layers 400 may be polysilicon. The formation of the padding layers 400 in contact with the source region 111 and/or the drain region 112 through the windows 311 specifically includes the following operations.

Polysilicon is deposited, and the polysilicon fills the windows 311 and covers the region other than the windows 311.

And, the polysilicon is etched back, the polysilicon in the region other than the windows 311 and part of the polysilicon at the tops of the windows 311 are removed, part of the polysilicon at the bottoms of the windows 311 is retained, and then, the retained polysilicon forms the padding layers 400. In this step, whether to remove part of the polysilicon in the windows 311 can be determined according to the required thickness of the padding layers 400. If the required padding layers 400 are thicker, part of the polysilicon in the windows 311 may not be removed, and only the polysilicon on the first dielectric layer 310 is removed.

Since the padding layers 400 have the second conductive type, the polysilicon formed above should also be doped with doped impurities having the second conductive type, and the polysilicon can be doped in different stages according to specific process conditions. In an example, the polysilicon can be doped during the deposition of the polysilicon, so that the deposited polysilicon has the second conductive type. In another example, undoped polysilicon can be deposited first, and after the polysilicon is etched back, the retained polysilicon is doped to form the padding layers 400 having the second conductive type.

At step S240, a second dielectric layer is formed on the first dielectric layer and the padding layers, and the second dielectric layer is provided with contact holes penetrating through the second dielectric layer and extending into the padding layers.

As shown in FIG. 3D, the second dielectric layer 320 is formed on the first dielectric layer 310 and the padding layers 400, and the second dielectric layer 320 is provided with contact holes 321 penetrating through the second dielectric layer 320 and extending into the padding layers 400 to expose the padding layers 400. Specifically, the width of the padding layers 400 does not exceed the width of the source region 111 and/or the drain region 112 below the padding layers 400, and the aperture of the contact holes 321 is less than the width of the padding layers 400. Further, the projections of the contact holes 321 are located in the middle regions of the padding layers 400. Specifically, the second dielectric layer 320 may also be silicon oxide.

In an example, the process of obtaining the above-mentioned second dielectric layer 320 and contact holes 321 may include the following operations.

The second dielectric layer 320 is deposited on the first dielectric layer 310 between the padding layers 400.

The upper surface of the second dielectric layer 320 is ground so that the second dielectric layer 320 has a flat upper surface.

A mask is formed on the second dielectric layer 320, arrangement positions of the contact holes 321 are defined through the mask, and the arrangement positions are directly opposite to the padding layers 400.

The second dielectric layer 320 is etched to expose the padding layers 400.

The padding layers 400 are etched to form the contact holes 321 penetrating through the second dielectric layer 320 and extending into the padding layers 400.

And, the mask is removed.

At step S250, the contact holes are filled with an electrode material to form electrodes in contact with the padding layers.

As shown in FIG. 3F, the contact holes 321 is filled with the electrode material, such as metal tungsten, to form electrodes 600 in contact with the padding layers 400, and the electrodes 600 are electrically connected with the source region 111 and/or the drain region 112 through the padding layers 400. The electrode 600 electrically connected with the source region 111 is a source electrode, and the electrode 600 electrically connected with the drain region 112 is a drain electrode.

The method for manufacturing the semiconductor device involved in this disclosure deposits the dielectric layer twice. The positions of the padding layers 400 are defined through the first dielectric layer 310, and then, the padding layers 400 superimposed on the source region 111 and/or the drain region 112 are formed; and the positions of the electrodes 600 are defined through the second dielectric layer 320, and then, the electrodes 600 of which the bottoms extend into the padding layers 400 are formed. Through the above-mentioned manufacturing method, the padding layers 400 are added above the source region 111 and/or the drain region 112. In the etching process of forming the contact holes 321, even if the accuracy of the etching process is not high, due to the addition of the padding layers 400, the distances between the electrodes 600 and depletion regions can be increased, so that the resistance between the electrodes 600 and the source region/the drain region is increased, and the voltage drop on the depletion regions is reduced, so as to reduce the junction leakage caused by the fact that the contact holes 321 are too close to the depletion layers. That is, the semiconductor device manufactured by the manufacturing method of this disclosure can reduce the junction leakage along a vertical direction, and the semiconductor device has better energy efficiency.

In an example, the padding layers 400 are polysilicon. After the contact holes 321 are formed and before materials of the electrodes 600 are filled in the contact holes 321, the method further includes the following operations.

The metal silicide 500 is formed on the exposed surfaces of the padding layers 400 through the contact holes 321.

As shown in FIG. 3E, when the contact holes 321 extend into the padding layers 400 and the padding layers 400 form grooves, the metal silicide 500 is formed on the surfaces of the grooves of the padding layers 400. By forming the metal silicide 500, the contact resistance between the electrodes 600 and the padding layers 400 can be further reduced. In a specific process, the steps of forming the metal silicide 500 comprise depositing a metal layer, and reacting the metal with silicon react under heating at a high temperature to generate the metal silicide 500. Specifically, the metal silicide 500 may be a cobalt silicide (CoSi).

It should be noted that the padding layer 400 may be formed only on the source region 111 or the drain region 112, or the padding layers 400 may be formed on both the source region 111 and the drain region 112, which is not limited. In addition, it should be noted that the drawings are only schematic diagrams, and the size relationship between the regions shown in the drawings is not the actual size relationship.

In an example, the above-mentioned semiconductor device includes a Metal-Oxide-Semiconductor Field-Effect Transistor (MOSFET). In addition, a gate structure 200 is also formed on the doped region 110 between the source region 111 and the drain region 112, and the gate structure 200 includes a gate dielectric layer 210 and a gate conductive layer 220 superimposed on the gate dielectric layer 210. Correspondingly, the first dielectric layer 310 formed in the step S220 also covers the gate structure 200, and the padding layers 400 and the gate structure 200 are isolated from each other to avoid electrical connection. Specifically, the gate dielectric layer 210 may be silicon oxide, and the gate conductive layer 220 may be polysilicon. In an example, one side of the source region 111 and/or the drain region 112 close to the gate structure 200 may also be provided with a lightly doped region 110 (LDD region) having the second conductive type and/or a pocket type heavily doped region 110 (Halo region) having the first conductive type. In an example, the above-mentioned semiconductor device may be a Dynamic Random Access Memory (DRAM), and the MOSFET having the above-mentioned structure is integrated in the DRAM. It can be understood that the above-mentioned semiconductor device is not limited to the DRAM.

Through the above-mentioned method for manufacturing the semiconductor device, the padding layers 400 are added above the source region 111 and/or the drain region 112. In the etching process of forming the contact holes 321, even if the accuracy of the etching process is not high, due to the addition of the padding layers 400, the distances between the electrodes 600 and depletion regions can be increased, so that the resistance between the electrodes 600 and the source region/the drain region is increased, and the voltage drop on the depletion regions is reduced, so as to reduce the junction leakage caused by the fact that the contact holes 321 are too close to the depletion layers. That is, the semiconductor device manufactured by the manufacturing method of this disclosure can reduce the junction leakage in a vertical direction, and the semiconductor device has better stability.

This disclosure also relates to a semiconductor device. The semiconductor device can be manufactured by the above-mentioned manufacturing method of the semiconductor device. Specifically, as shown in FIG. 3F, the semiconductor device includes a doped region 110, padding layers 400, an interlayer dielectric layer 300 and electrodes 600.

The source region 111 and/or the drain region 112 is formed on the surface layer of the doped region 110, the doped region 110 has a first conductive type, and the source region 111 and/or the drain region 112 have a second conductive type. That is, the conductive type of the doped region 110 is opposite to the conductive type of the source region 111 and the drain region 112. The first conductive type is one of a P type and an N type, and the second conductive type is the other one of the P type and the N type. For example, when the first conductive type is the P type, the second conductive type is the N type; and when the first conductive type is the N type, the second conductive type is the P type. The conductive type of the doped region 110 is opposite to the conductive type of the source region 111 and the drain region 112. When an inversion layer is formed in the doped region 110, the region between the source region 111 and the drain region 112 can form a current path.

In an example, the doped region 110 may be a semiconductor substrate 100 having the first conductive type or an epitaxial layer having the first conductive type formed on the semiconductor substrate 100, or may be a well region having the first conductive type formed by doping the inside or epitaxial layer of the semiconductor substrate 100.

In an example, the isolation structure 130 is formed in the doped region 110, and adjacent source regions are isolated by the isolation structure 130.

The padding layers 400 are formed on the source region 111 and/or the drain region 112 and are in contact with the source region 111 and/or the drain region 112. The padding layers 400 also have the second conductive type. That is, the conductive type of the padding layers 400 is consistent with the conductive type of the source region 111 and/or the drain region 112. Further, the doping concentration of the padding layers 400 needs to be higher than the doping concentration of the source region 111 and/or the drain region 112, so as to form an ohmic contact between the padding layers 400 and the source region/the drain region. In an example, the width of the padding layers 400 does not exceed the width of the source region 111 and/or the drain region 112 below the padding layers. Specifically, the padding layers 400 may be doped polysilicon.

The interlayer dielectric layer 300 is formed on the doped region 110 and the padding layers 400. That is, the interlayer dielectric layer 300 is formed on the padding layers 400 and covers the region other than the padding layers 400. Specifically, the interlayer dielectric layer 300 may be silicon dioxide.

The electrodes 600 penetrate through the interlayer dielectric layer 300 and extend into the padding layers 400 so as to be electrically connected with the padding layers 400, thereby realizing electrical connection with the source region 111 and/or the drain region 112 through the padding layers 400. The electrode 600 electrically connected with the source region 111 is a source electrode, and the electrode 600 electrically connected with the drain region 112 is a drain electrode. The width of the electrodes 600 is less than the width of the padding layers 400. Specifically, the regions in which the padding layers 400 are in contact with the electrodes 600 are located in the middle regions of the padding layers 400. Specifically, the electrode material forming the electrodes 600 is metal tungsten.

In an example, the material of the padding layers 400 is polysilicon, and the metal silicide 500 is also formed on contact surfaces of the padding layers 400 and the electrodes 600, so as to reduce the contact resistance between the electrodes 600 and the padding layers 400. Specifically, the metal silicide 500 may be a cobalt silicide (CoSi).

It should be noted that the padding layer 400 may be formed only on the source region 111 or the drain region 112, or the padding layers 400 may be formed on both the source region 111 and the drain region 112, which is not limited in the present disclosure. In addition, it should be noted that the drawings are only schematic diagrams, and the size relationship between the regions shown in the drawings is not the actual size relationship.

In an example, the above-mentioned semiconductor device includes a Metal-Oxide-Semiconductor Field-Effect Transistor (MOSFET). In addition, a gate structure 200 is also formed on the doped region 110 between the source region 111 and the drain region 112, and the gate structure 200 includes a gate dielectric layer 210 and a gate conductive layer 220 superimposed on the gate dielectric layer 210. Correspondingly, the first dielectric layer 310 formed in the step S220 also covers the gate structure 200, and the padding layers 400 and the gate structure 200 are isolated from each other to avoid electrical connection. Specifically, the gate dielectric layer 210 may be silicon oxide, and the gate conductive layer 220 may be polysilicon. In an example, one side of the source region 111 and/or the drain region 112 close to the gate structure 200 may also be provided with a lightly doped region 110 (LDD region) having the second conductive type and/or a pocket type heavily doped region 110 (Halo region) having the first conductive type. In an example, the above-mentioned semiconductor device may be a Dynamic Random-Access Memory (DRAM), and the MOSFET having the above-mentioned structure is integrated in the DRAM. It can be understood that the above-mentioned semiconductor device is not limited to the DRAM.

In the above-mentioned semiconductor device, the padding layers 400 are added above the source region 111 and/or the drain region 112. In the etching process of forming the contact holes 321, even if the accuracy of the etching process is not high, due to the addition of the padding layers 400, the distances between the electrodes 600 and depletion regions can be increased, so that the resistance between the electrodes 600 and the source region/the drain region is increased, and the voltage drop on the depletion regions is reduced, so as to reduce the junction leakage caused by the fact that the electrodes 600 are too close to the depletion layers. That is, the semiconductor device in this disclosure can reduce the junction leakage in a vertical direction, and the semiconductor device has better energy efficiency.

The above examples only describe several implementation modes of the present application. The description is specific and detailed, but cannot be understood as limitations to a scope of the present application. It is noted that those of ordinary skill in the art can further make multiple modifications and improvements without departing from a concept of the present application and those also belong to the protection scope of the present application. Therefore, the protection scope of the present application shall only be limited by the appended claims.

What is claimed is:

1. A method for manufacturing a semiconductor device, comprising:
forming a source region and/or a drain region on a surface layer of a doped region, wherein the doped region has a first conductive type, and the source region and the drain region have a second conductive type;
forming a first dielectric layer on the doped region, wherein the first dielectric layer is arranged with windows exposing the source region and/or the drain region;
forming padding layers in contact with the source region and/or the drain region through the windows, wherein the padding layers have the second conductive type;
forming a second dielectric layer on the first dielectric layer and the padding layers, wherein the second dielectric layer is arranged with contact holes penetrating through the second dielectric layer and extending into the padding layers; and
filling the contact holes with an electrode material to form electrodes in contact with the padding layers.

2. The method for manufacturing the semiconductor device of claim 1, wherein the formation of the first dielectric layer on the doped region comprises:
depositing the first dielectric layer on the doped region, wherein the first dielectric layer covers an entire upper surface of the doped region;
grinding an upper surface of the first dielectric layer so that the first dielectric layer has a flat upper surface;
forming a mask on the first dielectric layer, and defining arrangement positions of the windows through the mask, wherein the arrangement positions are directly opposite to the source region and/or the drain region;
etching the first dielectric layer to form the windows exposing the source region and/or the drain region; and
removing the mask.

3. The manufacturing method of the semiconductor device of claim 1, wherein the formation of the second dielectric layer on the first dielectric layer and the padding layers comprises:
depositing the second dielectric layer on the first dielectric layer between the padding layers;
grinding the upper surface of the second dielectric layer so that the second dielectric layer has a flat upper surface;
forming a mask on the second dielectric layer, and defining arrangement positions of the contact holes through the mask, wherein the arrangement positions are directly opposite to the padding layers;
etching the second dielectric layer to expose the padding layers;
etching the padding layers to form contact holes penetrating through the second dielectric layer and extending into the padding layers; and
removing the mask.

4. The manufacturing method of the semiconductor device of claim 1, wherein a material of the padding layers is polysilicon, and a doping concentration of the padding layers is greater than a doping concentration of the source region and/or the drain region.

5. The manufacturing method of the semiconductor device of claim 4, wherein the formation of the padding layers in contact with the source region and/or the drain region through the windows comprises:
depositing polysilicon, the polysilicon filling the windows and covering a region other than the windows; and
back etching the polysilicon, removing the polysilicon in the region other than the windows and the polysilicon at tops of the windows, and retaining the polysilicon at bottoms of the windows to form the padding layers.

6. The manufacturing method of the semiconductor device of claim 5, wherein during the deposition of polysilicon, the polysilicon is doped so that the deposited polysilicon has the second conductive type.

7. The manufacturing method of the semiconductor device of claim 5, wherein after the polysilicon at the bottoms of the windows is retained, the retained polysilicon is doped to form the padding layers having the second conductive type.

8. The manufacturing method of the semiconductor device of claim 4, wherein the method further comprises, before filling the contact holes with the electrode material,
forming a metal silicide on a surface of the padding layer exposed through the contact holes].

9. The manufacturing method of the semiconductor device of claim 1, wherein both the first dielectric layer and the second dielectric layer are silicon dioxide.

10. The manufacturing method of the semiconductor device of claim 1, wherein the semiconductor device is a Dynamic Random-Access Memory.

11. A semiconductor device, comprising:
a doped region, wherein a source region and/or a drain region is formed on a surface layer of the doped region, the doped region has a first conductive type, and the source region and the drain region have a second conductive type;
padding layers formed on the source region and/or the drain region and in contact with the source region and/or the drain region, wherein the padding layers have the second conductive type;
a dielectric layer formed on the doped region and the padding layers; and
electrodes penetrating through the dielectric layer and extending into the padding layers so as to be electrically connected with the padding layers.

12. The semiconductor device of claim 11, wherein a material of the padding layer is polysilicon, and a doping concentration of the padding layer is greater than a doping concentration of the source region and/or the drain region.

13. The semiconductor device of claim 11, wherein a metal silicide is also formed on contact surfaces of the padding layers and the electrodes.

14. The semiconductor device of claim 11, wherein the doped region is a semiconductor substrate having the first conductive type or a well region having the first conductive type formed in a semiconductor substrate.

15. The semiconductor device of claim 14, wherein the doped region is an epitaxial layer having the first conductive type formed on the semiconductor substrate.

16. The semiconductor device of claim 14, wherein an isolation structure is provided in the doped region to isolate adjacent source regions.

17. The semiconductor device of claim 11, wherein the padding layers are formed on the source region and/or the drain region and are in contact with the source region and/or the drain region, and the conductive type of the padding layers is consistent with the conductive type of the source region and/or the drain region.

18. The semiconductor device of claim 11, wherein a doping concentration of the padding layers is higher than a doping concentration of the source region and/or the drain region, so as to form an ohmic contact between the padding layers and the source region/the drain region.

19. The semiconductor device of claim 11, wherein a width of the padding layer does not exceed a width of the source region and/or the drain region below the padding layer.

20. The semiconductor device of claim 11, wherein the semiconductor device is a Dynamic Random-Access Memory.
